(19) United States
(12) Patent Application Publication
(10) Pub. No.: US 2026/0324442 A1
(43) Pub. Date: Oct. 15, 2026

(54) Integrated High Speed Module with large integrated inductors having embedded magnetic material

(71) Applicant: HRL Laboratories, LLC, Malibu, CA (US)

(72) Inventors: Avantika SODHI, Malibu, CA (US); Greg BRACY, Malibu, CA (US); John CARLSON, Malibu, CA (US)

(73) Assignee: HRL Laboratories, LLC, Malibu, CA (US)

(21) Appl. No.: 19/178,726

(22) Filed: Apr. 14, 2025

(51) Int. Cl. H01L 23/64; H01L 23/00; H01L 23/538; H01L 23/66; H01L 25/00; H01L 25/16; H10D 1/00; H10D 1/20

(52) U.S. Cl. CPC H10W 44/501; H10D 1/01; H10D 1/20; H10W 44/20; H10W 70/614; H10W 90/00; H10W 90/794

(57) ABSTRACT

An electronic assembly, including a carrier wafer that comprises an integrated circuit and a through-wafer cavity; a high frequency component chip held in the through-wafer cavity by direct contact with an attachment metal that fills at least a portion of the cavity; and a conductor connecting the integrated circuit to the high frequency component chip; wherein the electronic integrated circuit comprises an inductor having at least one conductive loop; the conductive loop having a loop axis parallel to bottom and top wafer surfaces and at least one portion of the loop comprising a conductive via that traverses the carrier wafer and connects a lower conductive segment to an upper conductive segment; the lower and upper conductive segments being parallel to the bottom and top wafer surfaces.

### RELATED APPLICATIONS

This application relates to U.S. Pat. No. 10,998,273, entitled “Hybrid Integrated Circuit Architecture”, filed Oct. 11, 2018; which is hereby incorporated by reference in its entirety. This application relates to U.S. patent application Ser. No. ______ entitled “DENSE POWER SUPPLY ASSEMBLIES AND METHOD OF MAKING THEREOF”, filed concurrently with the present application, which is hereby incorporated by reference in its entirety.

### TECHNICAL FIELD

This presentation relates to integrated electronic modules or assemblies; in particular to hybrid assemblies comprising circuits made of different materials assembled together by electrometallurgy; in particular to assemblies provided to operate at high speed; in particular to power electronics assemblies.

### BACKGROUND

GaN devices can operate at switching frequencies of several megahertz or even tens of megahertz making them 100 times faster than silicon devices. GaN has superior material properties such as high carrier mobility, low on-resistance, and low parasitic capacitance. These properties make GaN devices suitable choices for applications such as power electronics. In power electronics, high switching frequencies can reduce the size and weight of the components used in the circuit, while also improving efficiency.

Advances in interposer and 3D integration technologies enable the manufacture of ultra-compact multi-chip modules. Contemporary multi-chip power modules, such as Switched Mode Power Supplies (SMPS) use discrete transistors and passive components integrated on ceramic or organic substrates using flip-chip or wire-bond interconnects. Popular SMPS with discrete devices have gate drivers and voltage regulators designed in silicon and GaN transistors that are used as switches. For system cost considerations the number of GaN transistors are restricted to only that which are essential

The reference entitled “28 GHZ GaAs pHEMT MMICs and RF front-end module for 5G communication systems”, by Ahn, Hyun & Chang, Won & Kim, Seung & Park, Bok & Yook, Jong & Eo, Yun Seong. (2019), in Microwave and Optical Technology Letters. 61. 10.1002/mop.31669, which is hereby incorporated by reference in its entirety, discloses a 28 GHz switch and LNA chipset, and a RF front-end module for 5G communication systems. The 28 GHz Single Pole Double Throw (SPDT) switch and LNA MMICs are embedded in a single RF front-end module successfully using molding based embedded Wafer-Level Package (eWLP) technology. For the low noise figure and high isolation, inductive source degenerated LNA topology and double shunt FET structure for SPDT switch are employed, and LNA and SPDT are implemented in a single IC. The eWLP based package minimizes the parasitic component such as bond-wire inductance and signals loss to enhance the performance of the RF front-end module. At 28 GHZ, the measured gain and noise figure of the receiver path are 15.5 dB and 3.46 dB, respectively, and the IIP3 is +3 dBm at 45 mW power consumption.

The reference entitled “Electric Characteristics of Planar Interconnect Technologies for Power MOSFETs”, by S. Dieckerhoff et al., in 2007 IEEE Power Electronics Specialists Conference, Orlando, FL, USA, 2007, pp. 1036-1042, doi: 10.1109/PESC.2007.4342134, which is hereby incorporated by reference in its entirety, discloses two planar interconnection technologies for power semiconductors—a Flip Chip solution with a flexible substrate and a Chip-in-Polymer approach. These technologies substitute the wire bonds which are usually applied to contact the top side pads of power semiconductors. The process flow of the technology developments is explained. Exemplarily, prototypes are built applying fast switching MOSFETs in the voltage class up to 100 V. Based on these prototypes, experimental and simulation results with regard to the thermo-electric characteristics of the prototypes are discussed.

The reference, entitled “Maximizing GaN power transistor performance with embedded packaging”, by J. Roberts, in Proc. APEC, Charlotte, NC, USA, March 2015, pp. 1-14, which is hereby incorporated by reference in its entirety, discloses embedded lateral GaN devices with small parasitic elements, in particular a low inductance packaging.

The reference entitled “A New Package of High-Voltage Cascode Gallium Nitride Device for Megahertz Operation” by W. Zhang et al., in IEEE Transactions on Power Electronics, vol. 31, no. 2, pp. 1344-1353, February 2016, doi: 10.1109/TPEL.2015.2418572, which is hereby incorporated by reference in its entirety, discloses lateral gallium nitride (GaN)-based high-electron-mobility transistor (HEMT) power devices with high current density, high switching speed, and low on-resistance in comparison to established silicon (Si)-based semiconductor devices. These superior characteristics make GaN HEMTs ideal for high-frequency, high-efficiency power conversion. Using efficient GaN HEMT devices switched at high frequency in power electronic systems could lead to an increase in power density as well as a reduction in the weight, size, and cost of the system. However, conventional packaging configurations often compromise the benefits provided by high-performance GaN HEMT devices, for example, by increasing the parasitic inductance and resistance in the current loops of the device. This undesirable package-induced performance degradation is prominent in the cascode GaN device, where the combination of a high-voltage depletion-mode GaN semiconductor and low-voltage enhancement-mode Si semiconductor is needed. In this study, a new package is introduced for high-voltage cascode GaN devices and is successfully demonstrated to make the device more suitable for megahertz operation. This packaging prototype for cascode GaN devices is fabricated in a power quad flat no-lead format with the new features of a stack-die structure, embedded external capacitor, and flip-chip configuration. The parasitic ringing in hard-switching turn-off and switching losses in soft-switching transitions are both effectively reduced for this newly packaged device compared with a traditional package using the same GaN and Si devices. Improved thermal dissipation capability is also realized using this new package for better reliability.

. The reference entitled “A Review of High-Speed GaN Power Modules: State of the Art, Challenges, and Solutions” by A. I. Emon, Mustafeez-ul-Hassan, A. B. Mirza, J. Kaplun, S. S. Vala and F. Luo, in IEEE Journal of Emerging and Selected Topics in Power Electronics, vol. 11, no. 3, pp. 2707-2729, June 2023, doi: 10.1109/JESTPE.2022”, which is hereby incorporated by reference in its entirety, discloses that Wide bandgap (WBG) devices are a desirable choice for high-density energy conversion systems. In high-speed hard-switching applications, voltage overshoot across device terminals, oscillations at gate loop, and electromagnetic interference (EMI) become harder to mitigate, and the overall system reliability is reduced. To address the key challenges and harness the benefits offered by these latest generations of devices, improved and advanced packaging structures are required, as packaging technology often has a critical impact on module performance and reliability. This reference summarizes the design procedure for power modules, essential parts, and available materials for the fabrication of a power module package. Moreover, it provides a review of commercially available gallium nitride-based high electron mobility transistors (GaN HEMTs) and state-of-the-art module packaging technologies adopted for them with a focus on module layout, module integration trends, and identifying their impacts on the GaN HEMT's performance. This reference also discusses major challenges faced by designers with GaN HEMTs in power electronics applications and their potential solutions, which is critical for the mainstream adoption of GaN HEMTs and defining the future technology roadmap.

The reference entitled “Substrate-Embedded Low-Resistance Solenoid Inductors for Integrated Voltage Regulators”, by T. Sun et al., in IEEE Transactions on Components, Packaging and Manufacturing Technology, vol. 10, no. 1, pp. 134-141, January 2020, doi: 10.1109/TCPMT.2019.2956528, which is hereby incorporated by reference in its entirety, discloses that integrated power conversion and delivery are the key to achieve high-efficiency and high-performance data processing. Power inductors with high power density and low dc resistance are the key enabler to realize miniaturized voltage regulators (VRs) with high efficiency. With the integrated voltage regulators (IVRs), interconnection length from the battery to the loads can be dramatically reduced, resulting in lower conduction loss and higher power efficiency. This reference demonstrates substrates with embedded high-power-density solenoid inductors with an ultralow dc resistance for the IVRs. By incorporating advanced metal-polymer magnetic composites as the cores, the inductors show a high inductance density of 7 nH/mm 2 with an ultralow dc resistance of 10 mQ. With a low thickness of <500 μm, the power inductors can be embedded into substrates and positioned close to the loads to realize the IVRs. A substrate-compatible panel-level process was developed to embed the magnetic-core inductors with high throughput and low cost. Compared with the air-core inductors, the magnetic core achieved four times improvement in inductance for the same de resistance, indicating substantial footprint reduction and improvement in efficiency.

The reference “Vertically laminated magnetic cores by electroplating Ni—Fe into micromachined Si”, by D. P. Arnold, I. Zana, F. Cros and M. G. Allen, in IEEE Transactions on Magnetics, vol. 40, no. 4, pp. 3060-3062, July 2004, doi: 10.1109/TMAG.2004.829013, which is hereby incorporated by reference in its entirety, discloses fabrication and characterization of vertically laminated, electrodeposited Ni—Fe magnetic cores in micromachined silicon for the low megahertz frequency range. Laminated cores were fabricated by etching vertical trenches (60-180/spl mu/m wide and 525/spl mu/m deep) through silicon wafers and directly plating Ni—Fe onto the etched sidewalls. The Ni—Fe was plated over a range of thicknesses (3-53/spl mu/m) in order to study the influence of eddy currents. The measured impedances in the range 10 kHz-40 MHz confirm the reduction of eddy current losses. This reference demonstrates a simple fabrication method for achieving high-aspect-ratio, vertically laminated magnetic cores where the geometry of the structures can be easily tailored for various applications.

The reference entitled “High-Q Three-Dimensional Microfabricated Magnetic-Core Toroidal Inductors for Power Supplies in Package” by H. T. Le et al., in IEEE Transactions on Power Electronics, vol. 34, no. 1, pp. 74-85, January 2019, doi: 10.1109/TPEL.2018.2847439”, which is hereby incorporated by reference in its entirety, discloses that the integration of power inductors is a roadblock in realizing highly miniaturized power supply in package (PSiP) and power supply on chip. Inductors in such power systems are used for energy storage and filtering, but they dominate in size and loss. This reference presents a novel three-dimensional in-silicon through-silicon via (TSV) magnetic-core toroidal inductor for PSIP. The magnetic powder based core is embedded into a TSV air-core inductor using a casting method. The unique air-core inductor design with a hollow core and suspended windings enables a complete core filling with microscale magnetic powders. The proposed casting method is simple, scalable, and generic for a wide range of magnetic powders. TSV magnetic-core inductors are fabricated in a compact size of 2.4 mm×2.4 mm×0.28 mm with the core content varying from 63 to 88 wt % of soft ferrite NiZn powders. The TSV magnetic-core toroidal inductors are fabricated and electrically characterized. Small-signal measurements show a threefold higher inductance of 112 nH and a 30% higher quality factor of 14.3 at 12.5 MHz for magnetic-core inductors compared with similar TSV air-core inductors. The small-signal measurement results are verified by the modeled results. The total core loss is characterized by large-signal measurements. A suitable inductor is implemented in a 12-MHz buck converter that operates in a zero-voltage-switching mode. The converter achieves a peak efficiency of 71.6% and an output power of 2.4 W while converting 12 to 5 V dc.

The reference entitled “Solenoid microinductors with anisotropic nanolaminated CoNiFe cores for high-frequency DC-DC power conversion”, by J. Kim, M. Kim and M. Allen, 2015 IEEE International Magnetics Conference (INTERMAG), Beijing, China, 2015, pp. 1-1, doi: 10.1109/INTMAG.2015.7157044”, which is hereby incorporated by reference in its entirety, discloses that there has recently been tremendous effort towards DC-DC converter miniaturization by developing advanced magnetic cores and chip-scale microinductors using microfabrication techniques. Specifically, the use of laminated soft metallic alloys (e.g., NiFe or CoNiFe) with appropriate lamination thickness enables increased inductance density and suppressed eddy-current losses at high frequencies, resulting in the miniaturization of DC-DC power converters. For such laminated cores, here, this reference presents anisotropic nanolaminated CoNiFe cores featuring a hard magnetic axis in the length direction. In general, anisotropic magnetic cores exhibit improved magnetic properties (e.g., higher permeability and lower loss) when flux flows in the direction parallel to the hard axis in the MHz frequency range and above. The fabricated cores were further incorporated into solenoid microinductors for on-chip power supply applications.

There exists a need for a compact high-frequency assemblies, in particular comprising integrated inductors.

### SUMMARY

Embodiments of this presentation comprise a method of forming a compact hybrid high-frequency assembly, such as a Switched Mode Power Supply (SMPS) assembly, comprising at least one inductor integrated in a wafer of a first material and a high frequency component chip, of a second material and embedded in a cavity of the wafer, wherein the inductor is formed of through-wafer vias joining conductors on top and bottom surfaces of the wafer. Eventually, a ferrite core can be embedded in the wafer to form a magnetic circuit of the inductor.

Embodiments of this presentation comprise a compact hybrid high-frequency assembly, such as a Switched Mode Power Supply (SMPS) assembly, obtained using the method above.

Embodiments of this presentation include an electronic assembly, comprising: a carrier wafer having a top wafer surface and a bottom wafer surface; an electronic integrated circuit being formed in the carrier wafer and comprising a first integrated circuit contact pad on the top wafer surface; said carrier wafer comprising a through-wafer cavity having walls that join said top wafer surface to said bottom wafer surface; a high frequency component chip having a component chip top surface, a component chip bottom surface and component chip side surfaces, the component chip being held in said through-wafer cavity by direct contact of at least a side surface of said component chip with an attachment metal that fills at least a portion of said through-wafer cavity; said component chip comprising at least one component chip contact pad on said component chip top surface; and a first conductor connecting said first integrated circuit contact pad and said component chip contact pad; wherein said electronic integrated circuit comprises an inductor having at least one conductive loop; the conductive loop having a loop axis parallel to the bottom and top wafer surfaces and at least one portion of the loop comprising a conductive via that traverses at least a portion of the carrier wafer and connects a lower conductive segment to an upper conductive segment; the lower and upper conductive segments being parallel to the bottom and top wafer surfaces.

According to embodiments of this presentation, said at least one conductive loop is arranged around a ferrite core aligned with said loop axis; said ferrite core being held in an inductor cavity of the carrier wafer.

According to embodiments of this presentation, the ferrite core forms, around a magnetic circuit axis that is normal to the bottom and top wafer surfaces, a closed magnetic circuit for a magnetic field generated by the conductive loop.

According to embodiments of this presentation the ferrite core has a torus shape, the axis of the torus being the ferrite axis.

According to embodiments of this presentation, said at least one conductive loop forms a continuous electrical conductor wrapped in a spiral around four parallelepipedic ferrite cores connected together into a ring; said ferrite cores being held in an inductor cavity of the carrier wafer.

According to embodiments of this presentation, said at least one conductive loop comprises a plurality of loops, each loop comprising a different conductive via that traverses a different at least a portion of the carrier wafer and connects a different lower conductive segment to a different upper conductive segment; the lower and upper conductive segments being parallel to the bottom and top wafer surfaces.

According to embodiments of this presentation, the lower conductive segment is arranged on the bottom wafer surface and the upper conductive segment is arranged on the top wafer surface.

According to embodiments of this presentation, the inductor cavity has inductor cavity walls and the ferrite core is held in the inductor cavity by direct contact with the inductor cavity walls.

According to embodiments of this presentation, the inductor cavity has inductor cavity walls and the ferrite core is attached by a polymer to the inductor cavity walls.

According to embodiments of this presentation, a top surface of the ferrite core is covered by a polymer layer.

Other embodiments of this presentation include a method of manufacturing an electronic assembly, the method comprising: providing a high frequency component chip having a component chip top surface, a component chip bottom surface and component chip side surfaces; said component chip comprising at least one component chip contact pad on said component chip top surface; providing a handle wafer having a first surface; attaching said component chip top surface to said first surface of said handle wafer; providing a carrier wafer having a top wafer surface and a bottom wafer surface; forming in the carrier wafer an electronic integrated circuit having a first integrated circuit contact pad on the top wafer surface; forming in the carrier wafer a through-wafer cavity having walls that join said top wafer surface to said bottom wafer surface; attaching said top wafer surface to said first surface of said handle wafer such that said component chip is arranged within said through-wafer cavity; filling at least a portion of said through-wafer cavity with an attachment metal so as to hold the component chip in said through-wafer cavity by direct contact of at least a side surface of said component chip with said attachment metal; detaching the handle wafer from the component chip top surface and the top wafer surface; and forming a first conductor between the first integrated circuit contact pad and said component chip contact pad; wherein said forming in the carrier wafer an electronic integrated circuit having a first integrated circuit contact pad on the top wafer surface comprises forming at least one conductive loop of an inductor, the conductive loop having a loop axis parallel to the bottom and top wafer surfaces; wherein said forming at least one conductive loop comprises forming a lower conductive segment parallel to the bottom wafer surface; forming a conductive via that traverses at least a portion of the carrier wafer and connects to the lower conductive segment; and forming an upper conductive segment parallel to the top wafer surfaces and connected to the conductive via.

According to embodiments of this presentation, said forming at least one conductive loop further comprises arranging a ferrite core in an inductor cavity of the carrier wafer, such that the ferrite core has an axis aligned with said loop axis.

According to embodiments of this presentation, the ferrite core forms, around a magnetic circuit axis normal to the bottom and top wafer surfaces, a closed magnetic circuit for a magnetic field generated by the conductive loop.

According to embodiments of this presentation, the ferrite core has a torus shape, the axis of the torus being the magnetic circuit axis.

According to embodiments of this presentation, said forming at least one conductive loop comprises forming a plurality of loops, each loop comprising a different conductive via that traverses a different at least a portion of the carrier wafer and connects a different lower conductive segment to a different upper conductive segment; the lower and upper conductive segments being parallel to the bottom and top wafer surfaces.

According to embodiments of this presentation, said forming a lower conductive segment comprises forming said lower conductive segment on the bottom wafer surface and said forming an upper conductive segment comprises forming said upper conductive segment on the top wafer surface.

According to embodiments of this presentation, the inductor cavity has inductor cavity walls and where said arranging a ferrite core in the inductor cavity comprises electroplating the inductor cavity walls with ferrite material.

According to embodiments of this presentation, the inductor cavity has inductor cavity walls and where said arranging a ferrite core in the inductor cavity comprises providing a ferrite core and attaching it with a polymer to the inductor cavity walls.

According to embodiments of this presentation, a top surface of the ferrite core is covered by a polymer layer.

Other embodiments of this presentation include a method of manufacturing an electronic assembly, the method comprising: providing a carrier wafer having top and bottom surfaces and etching an inductor cavity on at least one of the top and bottom surfaces of the carrier wafer; arranging in the inductor cavity a ferrite core that is attached to the carrier wafer; etching in the carrier wafer a through-wafer cavity and at least one through-wafer via, the at least one through-wafer via being on a side of the inductor cavity; attaching the top surface of the carrier wafer to a handle wafer; providing a high frequency component chip having a component chip top surface, a component chip bottom surface and component chip side surfaces; said component chip comprising at least one component chip contact pad on said component chip top surface; attaching the top surface of said component chip to a portion of the handle wafer, in the through-wafer cavity of the carrier wafer; filling the at least one through-wafer via and the through-wafer cavity of the carrier wafer with a metal by electroplating; passivating the bottom surface of the carrier wafer; forming on the bottom surface of the carrier wafer at least one lower conductive segment connected to the at least one through wafer via; removing the handler wafer and passivating the top surface of the carrier wafer; and forming on the top surface of the carrier wafer a metal layer comprising at least one upper conductive segment connected to the at least one through wafer via, such that the at least one upper and lower conductive segments and the at least one through wafer via form a portion of a conductive loop of an inductor arranged to generate a magnetic field in said ferrite core; and at least a connection between the at least one high frequency component contact pad and a contact pad of a circuit comprising said inductor.

### FIGURES

The above features will now be described in more details in relation with the following figures, wherein:

FIG. 1A illustrates a cross section of a high speed electronic assembly according to embodiments of this presentation.

FIG. 1B illustrates a projection view of an inductor of the assembly of FIG. 1A.

FIG. 2A illustrates a method of manufacturing a high speed electronic assembly according to embodiments of this presentation.

FIG. 2B illustrates a method of manufacturing a high speed electronic assembly according to embodiments of this presentation.

FIGS. 3A to 3I illustrate a cross section view of steps of manufacturing of a high speed electronic assembly according to embodiments of this presentation.

### DETAILED DESCRIPTION

The following description is presented to enable one of ordinary skill in the art to make and use the teachings of this presentation and to incorporate them in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of embodiments of this presentation. However, it will be apparent to one skilled in the art that such embodiments may be practiced without necessarily being limited to these specilic details.

All the features disclosed in this presentation, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specilic function, is not to be interpreted as a “means” or “step” clause as specified in 35 U.S.C. Section 112(f). In particular, the use of “step of’ or ”act of’ in the claims herein is not intended to invoke the provisions of 35 U.S.C. 112, Paragraph 6.

Silicon is often used as a packaging material for 3D integration and microelectromechanical systems (MEMS) and often represents a large volume of wafer-level-packaged modules when compared against the volume occupied by active regions. Therefore, developing microfabrication technologies to embed components (e.g., passives, or MEMS devices) in the unused volume of the silicon package is a desirable approach to realize ultra-compact subsystems.

This presentation includes an innovative way to integrate inductors with GaN devices to form compact power supplies. Inductors are micro-fabricated inside silicon substrate by patterning and etching cavities in silicon and electrochemically plating or inserting micro-machined magnetic cores in the etched cavities. This method leverages advances in microfabrication technologies combined by high-resolution photolithography to fabricate dense inductors that can be integrated in high power switched mode power supplies.

Inductors embedded in silicon have been demonstrated previously. However, this presentation integrates inductors in substrates used for Metal Embedded Chip Assembly (MECA, as described in U.S. Pat. No. 10,998,273), where such substrates are also provided for receiving embedded high power or high frequency component chips. High power electronics such as GaN based switch mode power supplies require large inductors and efficient thermal management. Known embedded wafer level processes, thus far, embed ICs along with passives in epoxy matrix which has low thermal conductivity compared to for example silicon and copper. Embodiments of this presentation leverage superior heat spreading offered by MECA structures and embedded magnetic materials in silicon substrate to offer a platform where high performance component chips, such as GaN transistors that can switch at frequencies significantly higher than their silicon counterparts, can be combined with large inductors to form high power, high efficiency power supplies. Using high frequency components such as GaN transistors allows to reduce the size of passive components such as inductors and capacitors. Reducing the size of the inductors advantageously allows to manufacture them by embedding magnetic materials in the same silicon substrate in which the high frequency component chips are integrated.

Embedding together devices such as transistor chips and inductors in a silicon substrate reduces the interconnect lengths between the devices and allows for a path for interconnects to be patterned lithographically. This approach allows using un-packaged transistor ICs and un-packaged inductors which helps avoiding package parasitic in the interconnect path. In addition to the above advantages, the MECA process embeds the component chips (e.g. GaN transistor dies) in electroplated metal (e.g. copper), hence offering better heat spreading and a low thermal resistance path to heat extraction systems. Low interconnect parasitic and efficient thermal management are key to attaining optimal performance, for example when making SMPS assemblies. For example, embodiments of this presentation comprising SMPs that include GaN transistors allow restricting the temperature rise during transistor switching, which allows maintaining a high efficiency of the GaN transistors; and allows limiting the interconnect parasitics and therefore reducing resistive losses and avoiding instabilities due to loop inductances. Hence, according to embodiments of this presentation a significant size reduction for an SMPS system can be achieved while improving the efficiency compared to the existing solutions.

Embodiments of this presentation can be of interest to automotive companies working towards fully electric vehicles, because they allow packing ultra-high density efficient power supplies in a very compact footprint so that the range of travel for a given battery charge can be extended. Embodiments of this presentation also allow saving on the energy required for the cooling electronics. The compactness of power supply built using embodiments of this presentation can also be beneficial to space borne applications.

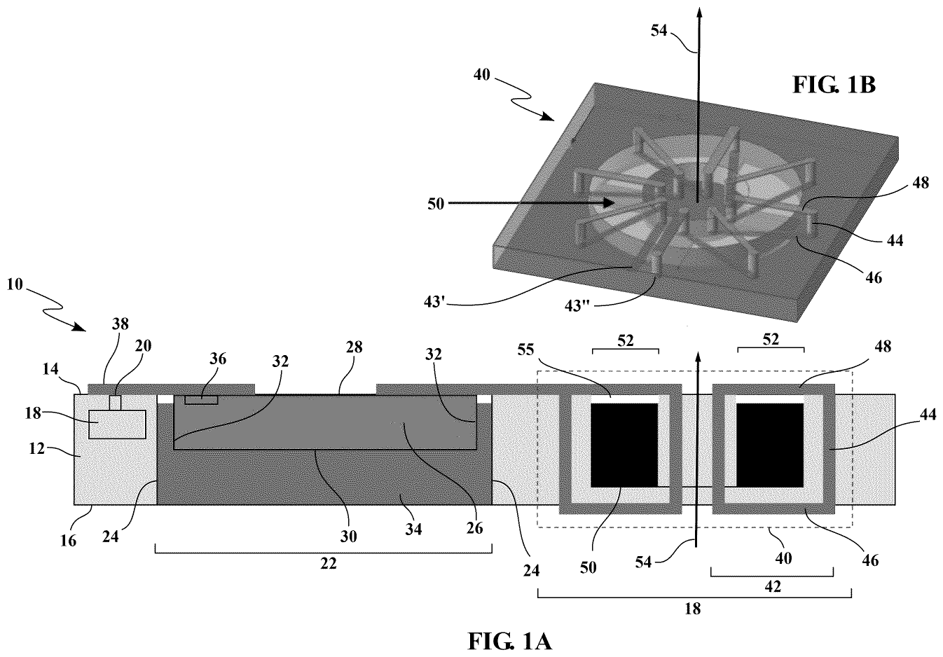

FIG. 1A illustrates a cross section of a high speed electronic assembly 10 according to embodiments of this presentation, comprising a carrier wafer 12 having a top wafer surface 14 and a bottom wafer surface 16. An integrated electronic circuit 18 is formed in the carrier wafer 12 and comprises at least one integrated circuit contact pad 20 on the top wafer surface 14. Circuit 18 can for example comprise transistor drivers. Carrier wafer 12 also comprises a through-wafer cavity 22 having walls 24 that join top wafer surface 14 to bottom wafer surface 16. Assembly 10 further comprises a high frequency component chip 26 that has a component chip top surface 28, a component chip bottom surface 30 and component chip side surfaces 32, where component chip 26 is held in through-wafer cavity 22 by direct contact of at least one of its side surfaces 32 with an attachment metal 34 that fills at least a portion of through-wafer cavity 22. Metal 34 can be electroformed copper, as detailed in U.S. Pat. No. 10,998,273. Component chip 26 comprises at least one component chip contact pad 36 on component chip top surface 28, and a first conductor 38, formed for example in a photolithography top metallization layer, connects the at least one integrated circuit contact pad 20 and the at least one component chip contact pad 36. The circuit 18 of assembly 10 further comprises an inductor 40 having at least one conductive loop 42; the at least one conductive loop 42 having a loop axis parallel to the bottom and top wafer surfaces 16, 14. According to embodiments of this presentation, inductor 40 comprises a plurality of conductive loops 42. The plurality of conductive loops can be arranged in a straight tunnel-like structure that have each the same loop axis. Alternatively, the plurality of conductive loops can be arranged in a ring-like structure, as illustrated hereafter, wherein the loop axis of each conductive loop is offset angularly with respect to the loop axes of the neighboring conductive loops.

As illustrated in FIG. 1B, inductor 40 can have a spring-like structure roughtly arranged in a ring shape, where the axis of the conductive loop forms a circle around which the spring-like structure coils itself. In such a configuration, the spring-like structure can comprise a plurality of straight conductors connected in series, where a first conductor 43′ of the spring-like inductor 40 can be arranged in the immediate vicinity of a last conductor 43″ of the spring-like inductor 40. According to embodiments of this presentation, the plurality of series-connected conductors of inductor 40 form a plurality of loops 42 connected in series, where the series-connected conductors of each loop comprise at least: a conductive via 44 that traverses the carrier wafer 12 from top to bottom; a lower conductive segment 46, formed on the bottom surface 16 of wafer 12 and connected in series with via 44; and an upper conductive segment 48 that is formed on the upper surface 14 of wafer 12 and is connected in series with via 44. The upper conductive segment 48 can be manufactured in the same metallization layer as conductor 38. The lower conductive segment 46 can be manufactured in a photolithography bottom metallization layer.

As illustrated in FIGS. 1A and 1B, according to embodiments of this presentation the spring-like inductor 40 can coil around a ferrite core 50 arranged symmetrically around the axis of the coil. The ferrite core 50 is illustrated as having the shape of a ring but it can have the shape of a torus, or any suitable shape to form a magnetic circuit for the inductor 40. For example, according to an embodiment that is not illustrated, the ferrite core can comprise four parallelepipedic ferrite cores connected together into a square ring.

According to embodiments of this presentation, the ferrite core 50 is held in an inductor cavity 52 of the carrier wafer. As illustrated in FIGS. 1A and 1B, the ferrite core 50 can form, around a magnetic circuit axis 54 that is normal to the bottom and top wafer surfaces 16, 14, a closed magnetic circuit for a magnetic field generated by the spring-like conductive loop of inductor 40. According to embodiments of this presentation, inductor cavity 52 has inductor cavity walls and ferrite core 50 is held in inductor cavity 50 by direct contact with the inductor cavity walls. In such embodiments, ferrite core 50 can be formed by electrometallurgy inside cavity 52.

Alternatively, ferrite core 50 can be manufactured first, then attached to the inductor cavity walls; for example by a glue and/or polymer. According to embodiments of this presentation, a top surface of ferrite core 50 can be covered by a polymer layer 55. Polymer layer can fill a top portion of the cavity 52 or it can be a passivation/dielectric layer formed at the surface of carrier wafer 12.

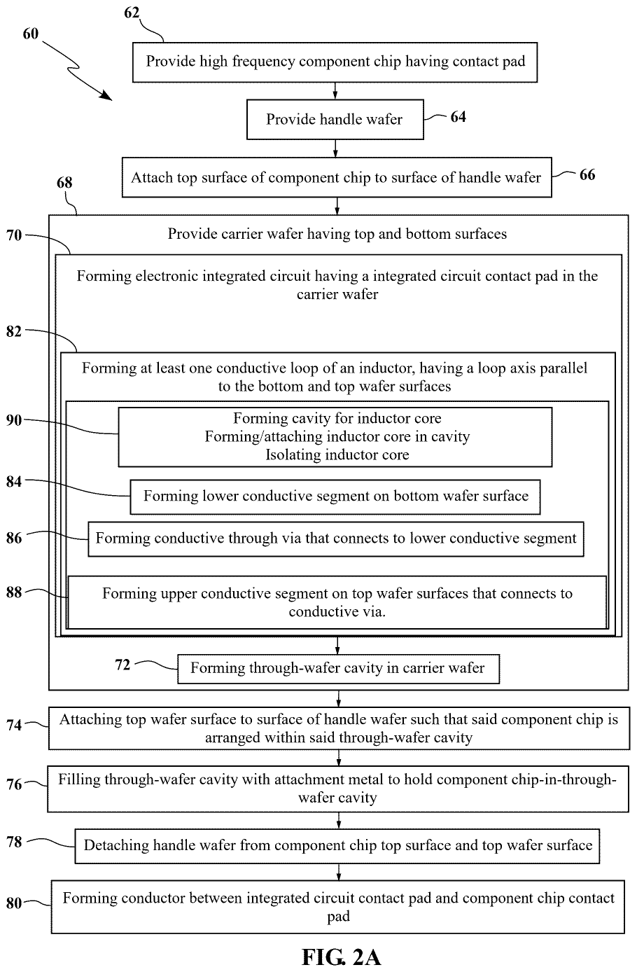

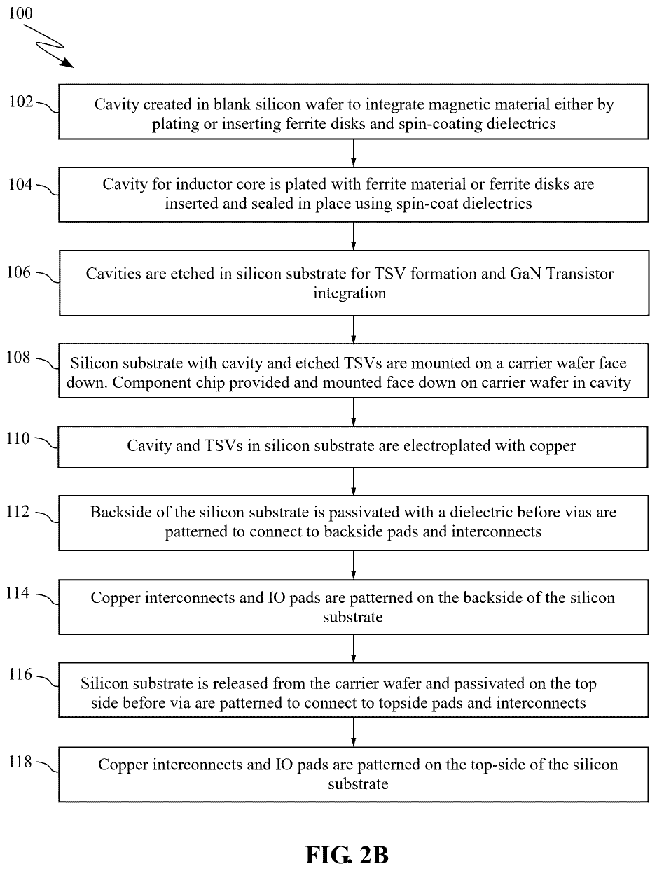

FIG. 2A illustrates a method 60 of manufacturing a high speed electronic assembly according to embodiments of this presentation. According to embodiments of this presentation, method 60 comprises providing 62 a high frequency component chip having a top surface, a bottom surface and side surfaces; said component chip comprising at least one contact pad on the component chip top surface. Method 60 then comprises providing 64 a handle wafer; and attaching 66 the top surface of the component chip to a surface of the handle wafer. Method 60 further comprises providing 68 a carrier wafer having top and bottom surfaces; forming 70 in the carrier wafer an electronic integrated circuit having at least one contact pad on its top surface; forming 72 in the carrier wafer a through-wafer cavity having walls that join the top and bottom surfaces of the carrier wafer. Method 60 then provides for attaching 74 the top surface of the carrier wafer to the surface of the handle wafer such that the component chip is arranged within the through-wafer cavity, and filling 76 at least a portion of the through-wafer cavity with an attachment metal so as to hold the component chip in the through-wafer cavity by direct contact of at least a side surface of said component chip with said attachment metal.

The method then includes detaching 78 the handle wafer from the component chip top surface and the top wafer surface; and forming 80 a conductor between the at least one contact pad of the integrated circuit and the at least one contact pad of the component chip contact pad.

According to embodiments of this presentation, the step 70 of forming in the carrier wafer an electronic integrated circuit comprises forming 82 at least one conductive loop of an inductor, the conductive loop having a loop axis parallel to the bottom and top wafer surfaces; and said forming 82 at least one conductive loop comprises forming 84 on the bottom surface of the carrier wafer a lower conductive segment; forming 86 a conductive via that traverses at least a portion of the carrier wafer and connects to the lower conductive segment; and forming 88 on the top surfaces of the carrier wafer an upper conductive segment that is connected to the conductive via. Preferably, the inductor comprises a plurality of conductive loops having each a via and top and bottom conductive segments, the conductive loops being connected in series using additional vias, for example as illustrated in FIG. 1B.

Optionally, in method 60, the step of forming 82 at least one conductive loop further comprises arranging 90 a ferrite core of the inductor in a cavity of the carrier wafer, such that the ferrite core is aligned with the axis of the loop. This arranging of the ferrite core 90 can comprise first forming a cavity for the ferrite core in the carrier wafer, then forming the ferrite core in the cavity, for example using electrometalurgy to fill a bottom portion of the cavity; or alternatively attaching a previously made ferrite core in the cavity, for example using glue or a polymer, then covering the ferrite core with an insulator such as a polymer.

The steps of method 60 as detailed above can be used to manufacture an electronic assembly such as detailed in relation to FIGS. 1A and 1B.

FIG. 2B illustrates a method 100 of manufacturing an electronic assembly according to other embodiments of this presentation. Method 100 comprises: providing 102 a carrier wafer having top and bottom surfaces and etching an inductor cavity on at least one of the top and bottom surfaces of the carrier wafer;

Method 100 further comprises arranging 104 in the inductor cavity a ferrite core that is attached to the carrier wafer. This can be done either by forming the ferrite core in the cavity using electrometallurgy or by gluing a previously formed ferrite core in the cavity, for example with a spin coat dielectric.

Method 100 further comprises etching 106 in the carrier wafer a through-wafer cavity and at least one through-wafer via (or Through-Substrate Via, or TSV), the at least one through-wafer via being on a side of the inductor cavity. In practice, a plurality of vias are generally formed so that a plurality of inductor loops connected in series can be made. Method 100 then comprises attaching 108 the top surface of the carrier wafer to a handle wafer; also providing 108 a high frequency component chip and attaching a top surface of said component chip to a portion of the handle wafer, in the through-wafer cavity of the carrier wafer. The at least one via (or plurality of vias) and the walls of the cavity can then be electroplated 110. The backside of the carrier wafer can then be passivated 112 and the at least one via (or plurality of vias) patterned before forming 114 at least a lower conductor to the at least one via with a lower metalization layer. In practice, when there is a plurality of vias to form a plurality of inductor loops, the conductors in the lower metalization layer form the lower parts of each loop.

Method 100 then comprises removing 116 the handler wafer, passivating the top surface of the carrier wafer and patterning the at least one via; then forming 118 on the top surface of the carrier wafer a metal layer comprising at least one upper conductive segment connected to the at least one via, such that the at least one upper and lower conductive segments and the at least one through wafer via form a portion of a conductive loop of an inductor arranged to generate a magnetic field in said ferrite core; and at least a connection between at least one contact pad of the component chip (for example a high frequency component) contact pad and a conductor of said inductor. Alternatively, the carrier wafer can comprise an integrated circuit, such as a driver circuit provided to operate with the inductor, and the at least one contact pad of the component chip can be connected to the interated circuit.

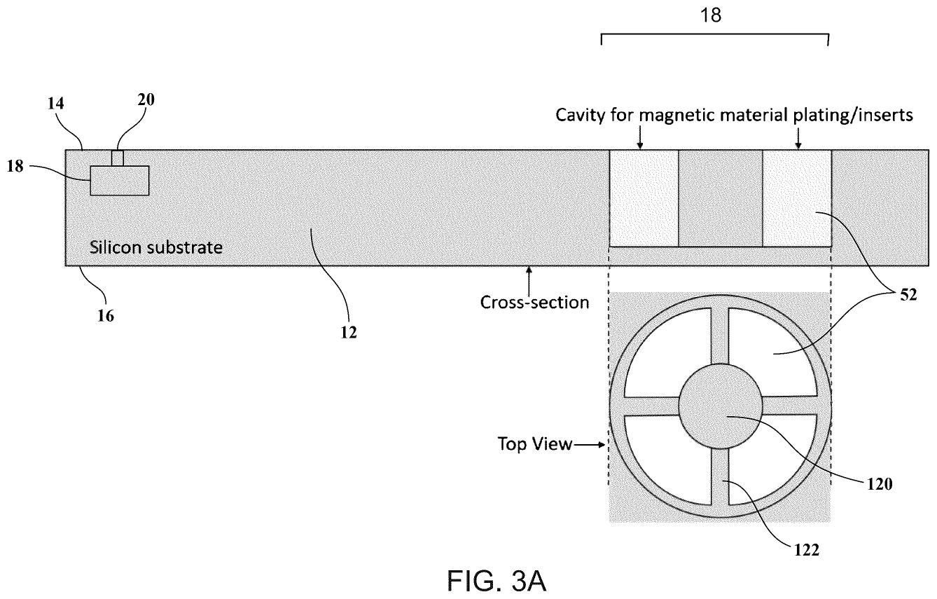

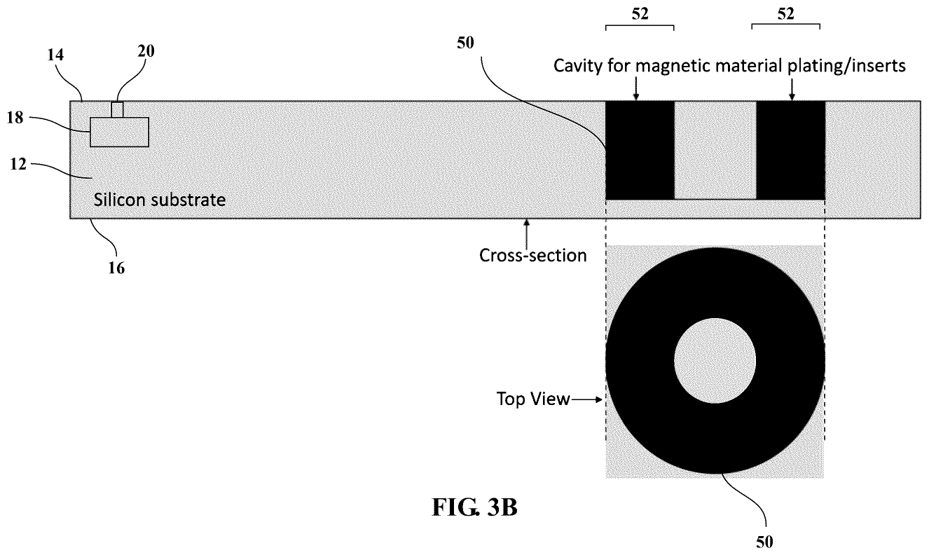

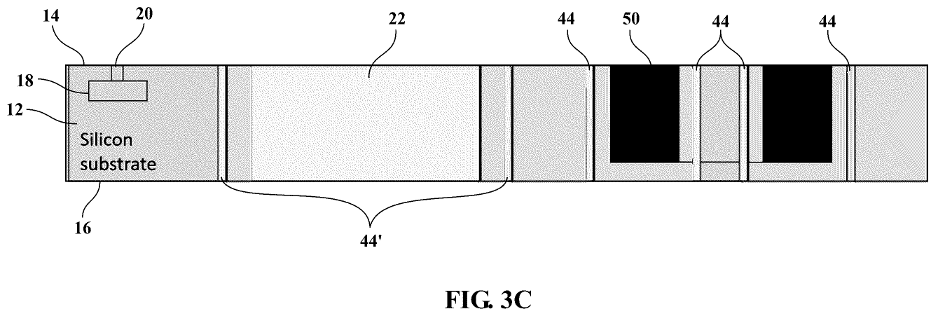

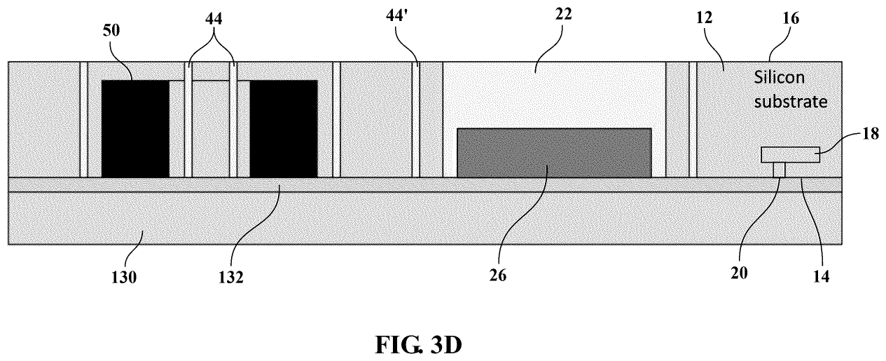

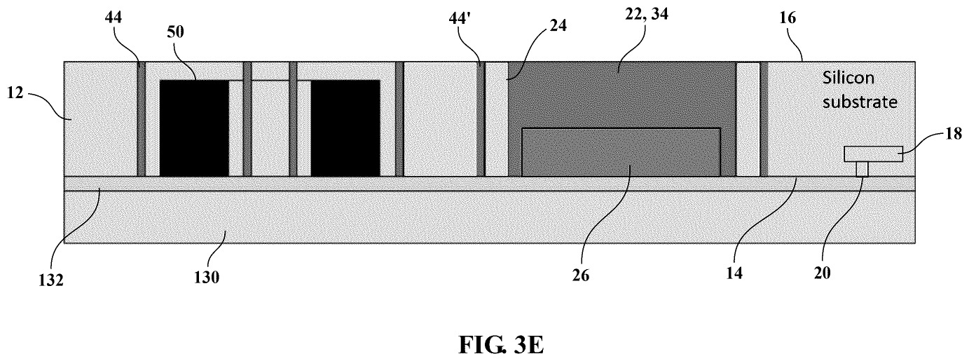

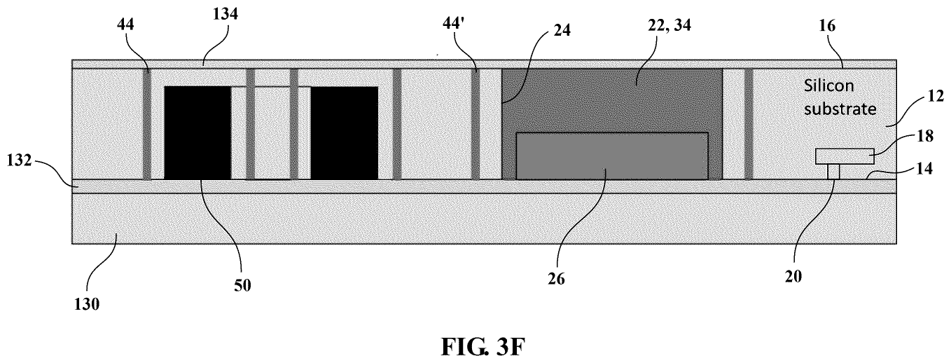

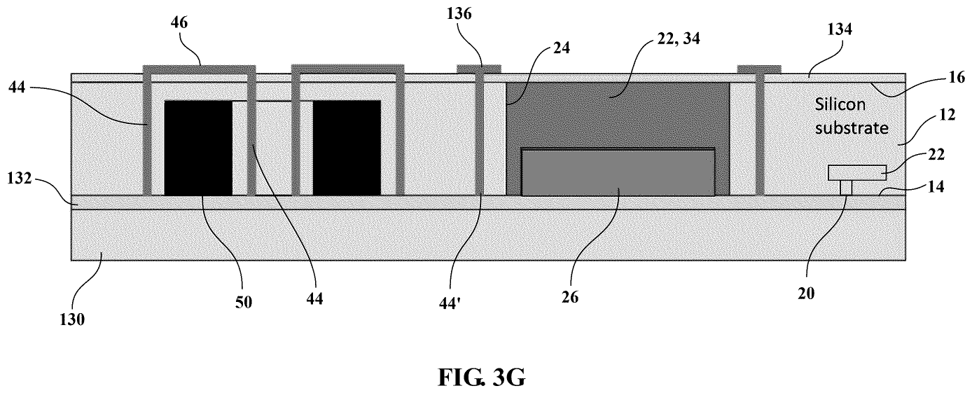

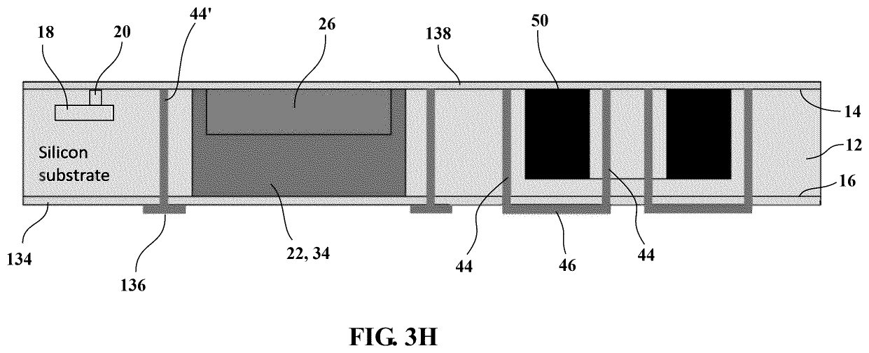

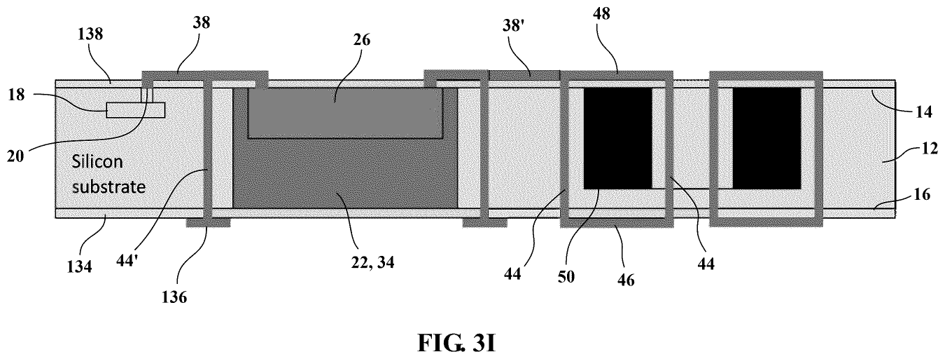

FIGS. 3A to 3I illustrate a cross section view of steps of manufacturing of a high speed electronic assembly such as shown in FIG. 1A.

FIG. 3A illustrates a carrier wafer 12 before it is attached to a handle wafer. As illustrated in FIG. 1A, carrier wafer 12 has top wafer surface 14 and bottom wafer surface 16. An integrated electronic circuit 18 is formed in carrier wafer 12 and comprises at least one integrated circuit contact pad 20 on the top wafer surface 14. Circuit 18 can comprise transistor drivers. Circuit 18 is provided to comprise at least one inductor 40, which can be arranged in a different region of carrier wafer 12 than the remainder of circuit 18. For example, a portion of circuit 18 can comprise active integrated components in one region of carrier wafer 12, which are coupled electrically to the inductor 40. In the example illustrated, the inductor will comprise a plurality of loops winding around a ring-shaped ferrite core. FIG. 3A shows a ring-shaped cavity 52 comprising a solid center 120 held in place by arms 122. The cavity 52, along with the center part 120 and the arms 122, can be made by photolithograpy. As illustrated in FIG. 3A, the arms 122 can form part of the bottom surface 16 of carrier wafer 12.

As illustrated in FIG. 3B, a ferrite core 50 is then arranged into cavity 52. symmetrically around the axis of the coil. The ferrite core 50 is illustrated as having the shape of a ring but it can have the shape of a torus, or any suitable shape to form a magnetic circuit for the inductor 40. For example, according to an embodiment that is not illustrated, the ferrite core can comprise four parallelepipedic ferrite cores connected together into a square ring.

According to embodiments of this presentation, the ferrite core 50 is held in an inductor cavity 52 of the carrier wafer. Ferrite core 50 can be formed by electrometallurgy inside cavity 52; or it can be manufactured first, then attached to the walls of inductor cavity 52; for example by a glue and/or polymer. According to embodiments of this presentation, a top surface of ferrite core 50 can be covered by a polymer layer 55 as shown in FIG. 1A. Alternatively, the top part of ferrite core 50 can be covered by a passivation/dielectric layer (not shown) formed at the surface of carrier wafer 12.

As illustrated in FIG. 3C, a through wafer cavity 22 as well as at least one through-wafer via 44 can then be pierced in wafer 12. The at least through-wafer via 44 allows forming a vertical portion of the inductor of integrated circuit 18. As shown in FIGS. 1A and 1B, when the inductor comprises a plurality of conductive loops, a plurality of vias 44 is provided to form the vertical portions of the conductive loops of the inductor. Some additional through-wafer vias 44′ can optionally be made, for example proximal to through wafer cavity 22, to pass signals from one side of the carrier wafer to the other.

As illustrated in FIG. 3D, according to embodiments of this presentation the wafer 12 is then flipped and its top surface 14 is temporarily glued/attached to a carrier wafer 130, for example using a layer of temporary adhesive 132. High frequency component chip 26 can also be temporarily glued/attached face down to the carrier wafer in the recess 22.

As illustrated in FIG. 3E, according to embodiments of this presentation the vias 44, 44′ and recess 22 can then be filled with metal, for example metal 34 in recess 22, for example using an electrometallurgy process. Filling recess 22 with metal 34 effectively attaches high frequency component chip 26 to the walls 24 of recess 22. Initially, a thin precursor layer of metal can be deposited on the walls of the vias and recess, as well as the exposed surfaces of the high frequency component 26, prior to filling the vias and recess with metal. The thin layer of precursor metal eases the electrometallurgy process.

As illustrated in FIG. 3F, according to embodiments of this presentation a passivation/dielectric layer 134 can then be formed on the bottom surface 16 of the wafer 12.

As illustrated in FIG. 3G, according to embodiments of this presentation a bottom metallization layer (for example copper) can then be formed on top of layer 134, then patterned to form lower conductive segments 46 connected to the bottom ends of vias 44 (now on top of the described structure as the wafer 12 is shown bottom-up). Optionally, the same bottom metallization layer can also be patterned to form contact pads 136 connected to the bottom ends of vias 44′.

As illustrated in FIG. 3H, according to embodiments of this presentation wafer 12 can then be detached from handle wafer 130, for example by dissolving temporary attachment layer 132. A passivation/dielectric layer 138 can then be formed on the top layer 14 of wafer 12.

As illustrated in FIG. 3I, according to embodiments of this presentation a top metallization layer (for example copper) can then be formed on top of layer 138, then patterned to form upper conductive segments 48 connected to the top ends of vias 44, thus completing the spring-like conductive loop of inductor 40. Optionally, the same top metallization layer can also be patterned to form conductors 38, 38′ that can connect the integrated circuit 18 to the high frequency component chip 26 and/or to the contact pads 136 by way of the vias 44′, and/or to the inductor 40.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom.

Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112(f), sixth paragraph, unless the element is expressly recited using the phrase “means for . . . ” and no method or process step herein is to be construed under those provisions unless the step, or steps, are expressly recited using the phrase “comprising the step(s) of . . . ”

All elements, parts and steps described herein are preferably included. It is to be understood that any of these elements, parts and steps may be replaced by other elements, parts and steps or deleted altogether as will be obvious to those skilled in the art.

1. An electronic assembly, comprising:
a carrier wafer having a top wafer surface and a bottom wafer surface;
an electronic integrated circuit being formed in the carrier wafer and comprising a first integrated circuit contact pad on the top wafer surface;
said carrier wafer comprising a through-wafer cavity having walls that join said top wafer surface to said bottom wafer surface;
a high frequency component chip having a component chip top surface, a component chip bottom surface and component chip side surfaces, the component chip being held in said through-wafer cavity by direct contact of at least a side surface of said component chip with an attachment metal that fills at least a portion of said through-wafer cavity;
said component chip comprising at least one component chip contact pad on said component chip top surface; and
a first conductor connecting said first integrated circuit contact pad and said component chip contact pad;
wherein said electronic integrated circuit comprises an inductor having at least one conductive loop; the conductive loop having a loop axis parallel to the bottom and top wafer surfaces and at least one portion of the loop comprising a conductive via that traverses at least a portion of the carrier wafer and connects a lower conductive segment to an upper conductive segment; the lower and upper conductive segments being parallel to the bottom and top wafer surfaces.

2. The electronic assembly of claim 1, wherein said at least one conductive loop is arranged around a ferrite core aligned with said loop axis; said ferrite core being held in an inductor cavity of the carrier wafer.

3. The electronic assembly of claim 2, wherein the ferrite core forms, around a magnetic circuit axis that is normal to the bottom and top wafer surfaces, a closed magnetic circuit for a magnetic field generated by the conductive loop.

4. The electronic assembly of claim 3, wherein the ferrite core has a torus shape, the axis of the torus being the ferrite axis.

5. The electronic assembly of claim 1, wherein said at least one conductive loop forms a continuous electrical conductor wrapped in a spiral around four parallelepipedic ferrite cores connected together into a ring; said ferrite cores being held in an inductor cavity of the carrier wafer.

6. The electronic assembly of claim 1, wherein said at least one conductive loop comprises a plurality of loops, each loop comprising a different conductive via that traverses a different at least a portion of the carrier wafer and connects a different lower conductive segment to a different upper conductive segment; the lower and upper conductive segments being parallel to the bottom and top wafer surfaces.

7. The electronic assembly of claim 1, wherein the lower conductive segment is arranged on the bottom wafer surface and the upper conductive segment is arranged on the top wafer surface.

8. The electronic assembly of claim 2, where the inductor cavity has inductor cavity walls and where the ferrite core is held in the inductor cavity by direct contact with the inductor cavity walls.

9. The electronic assembly of claim 2, where the inductor cavity has inductor cavity walls and where the ferrite core is attached by a polymer to the inductor cavity walls.

10. The electronic assembly of claim 2, wherein a top surface of the ferrite core is covered by a polymer layer.

11. A method of manufacturing an electronic assembly, comprising:
providing a high frequency component chip having a component chip top surface, a component chip bottom surface and component chip side surfaces; said component chip comprising at least one component chip contact pad on said component chip top surface;
providing a handle wafer having a first surface; attaching said component chip top surface to said first surface of said handle wafer;
providing a carrier wafer having a top wafer surface and a bottom wafer surface; forming in the carrier wafer an electronic integrated circuit having a first integrated circuit contact pad on the top wafer surface; forming in the carrier wafer a through-wafer cavity having walls that join said top wafer surface to said bottom wafer surface; attaching said top wafer surface to said first surface of said handle wafer such that said component chip is arranged within said through-wafer cavity;
filling at least a portion of said through-wafer cavity with an attachment metal so as to hold the component chip in said through-wafer cavity by direct contact of at least a side surface of said component chip with said attachment metal;
detaching the handle wafer from the component chip top surface and the top wafer surface; and
forming a first conductor between the first integrated circuit contact pad and said component chip contact pad; wherein said forming in the carrier wafer an electronic integrated circuit having a first integrated circuit contact pad on the top wafer surface comprises forming at least one conductive loop of an inductor, the conductive loop having a loop axis parallel to the bottom and top wafer surfaces; wherein said forming at least one conductive loop comprises forming a lower conductive segment parallel to the bottom wafer surface; forming a conductive via that traverses at least a portion of the carrier wafer and connects to the lower conductive segment; and forming an upper conductive segment parallel to the top wafer surfaces and connected to the conductive via.

12. The method of claim 11, wherein said forming at least one conductive loop further comprises arranging a ferrite core in an inductor cavity of the carrier wafer, such that the ferrite core is aligned with said loop axis.

13. The method of claim 12, wherein the ferrite core forms, around a magnetic circuit axis normal to the bottom and top wafer surfaces, a closed magnetic circuit for a magnetic field generated by the conductive loop.

14. The method of claim 13, wherein the ferrite core has a torus shape, the axis of the torus being the magnetic circuit axis.

15. The method of claim 11, wherein said forming at least one conductive loop comprises forming a plurality of loops, each loop comprising a different conductive via that traverses a different at least a portion of the carrier wafer and connects a different lower conductive segment to a different upper conductive segment; the lower and upper conductive segments being parallel to the bottom and top wafer surfaces.

16. The method of claim 11, wherein said forming a lower conductive segment comprises forming said lower conductive segment on the bottom wafer surface and said forming an upper conductive segment comprises forming said upper conductive segment on the top wafer surface.

17. The method of claim 12, where the inductor cavity has inductor cavity walls and where said arranging a ferrite core in the inductor cavity comprises electroplating the inductor cavity walls with ferrite material.

18. The method of claim 12, where the inductor cavity has inductor cavity walls and where said arranging a ferrite core in the inductor cavity comprises providing a ferrite core and attaching it with a polymer to the inductor cavity walls.

19. The method of claim 12, wherein a top surface of the ferrite core is covered by a polymer layer.

20. A method of manufacturing an electronic assembly, comprising:
providing a carrier wafer having top and bottom surfaces and etching an inductor cavity on at least one of the top and bottom surfaces of the carrier wafer;
arranging in the inductor cavity a ferrite core that is attached to the carrier wafer;
etching in the carrier wafer a through-wafer cavity and at least one through-wafer via, the at least one through-wafer via being on a side of the inductor cavity;
attaching the top surface of the carrier wafer to a handle wafer;
providing a high frequency component chip having a component chip top surface, a component chip bottom surface and component chip side surfaces; said component chip comprising at least one component chip contact pad on said component chip top surface;
attaching the top surface of said component chip to a portion of the handle wafer, in the through-wafer cavity of the carrier wafer;
filling the at least one through-wafer via and the through-wafer cavity of the carrier wafer with a metal by electroplating;
passivating the bottom surface of the carrier wafer;
forming on the bottom surface of the carrier wafer at least one lower conductive segment connected to the at least one through wafer via;
removing the handle wafer and passivating the top surface of the carrier wafer; and
forming on the top surface of the carrier wafer a metal layer comprising at least one upper conductive segment connected to the at least one through wafer via, such that the at least one upper and lower conductive segments and the at least one through wafer via form a portion of a conductive loop of an inductor arranged to generate a magnetic field in said ferrite core; and at least a connection between the at least one high frequency component contact pad and a contact pad of a circuit comprising said inductor.
